(19) United States
(12) Patent Application Publication
(10) Pub. No.: US 2024/0359285 A1
(43) Pub. Date: Oct. 31, 2024

(54) METHOD OF DETECTING A WRONG WORKPIECE WHICH IS NOT AN OBJECT TO BE POLISHED, AND OPTICAL FILM-THICKNESS MEASURING APPARATUS

(71) Applicant: EBARA CORPORATION, Tokyo (JP)

(72) Inventor: Yuki WATANABE, Tokyo (JP)

(21) Appl. No.: 18/642,234

(22) Filed: Apr. 22, 2024

(30) Foreign Application Priority Data
Apr. 28, 2023 (JP) 2023-073956

(51) Int. Cl. B24B 37/013

(52) U.S. Cl. CPC B24B 37/013

(57) ABSTRACT

A method capable of detecting a wrong workpiece (e.g., wafer), which is not an object to be polished, is disclosed. The method includes: creating inspection spectrum data of reflected light from a workpiece before polishing of the workpiece or after beginning of polishing of the workpiece; inputting the inspection spectrum data to an autoencoder; calculating a difference between output data from the autoencoder and the inspection spectrum data; and determining that, when the difference is larger than a threshold value, the workpiece used to create the inspection spectrum data is a wrong workpiece which is not an object to be polished.

### CROSS REFERENCE TO RELATED APPLICATION

This document claims priority to Japanese Patent Application No. 2023-073956 filed Apr. 28, 2023, the entire contents of which are hereby incorporated by reference.

### BACKGROUND

A manufacturing process for a semiconductor device includes various processes, such as a process of polishing a dielectric film (e.g., SiO₂) and a process of polishing a metal film (e.g., copper or tungsten). Manufacturing processes for a back-illuminated CMOS sensor and a through-silicon via (TSV) include a process of polishing a silicon layer (or a silicon wafer) in addition to the process of polishing the dielectric film or the metal film. Polishing of a wafer is terminated when a thickness of a film (e.g., dielectric film, metal film, silicon film) that forms a surface of the wafer has reached a predetermined target value.

Polishing of the wafer is performed using a polishing apparatus. In order to measure a thickness of a non-metal film, such as a dielectric film or a silicon layer, the polishing apparatus generally includes an optical film-thickness measuring device. This optical film-thickness measuring device is configured to direct light, emitted by a light source, to the surface of the wafer and analyze a spectrum of light reflected from the wafer to detect a film thickness of the wafer. When the film thickness of the wafer reaches a target value, polishing of the wafer is terminated.

Polishing of the wafer is performed in accordance with a polishing recipe that has been set in the polishing apparatus. This polishing recipe is different for each type of wafer, so that the polishing recipe needs to be changed based on the type of wafer to be polished. Moreover, if the types of wafer are different from each other, the spectra of light reflected from the wafer are also different, and thus conditions for detecting the polishing endpoint are also different.

If a wafer that is not an object to be polished (i.e., a wafer whose type is different and which does not match the polishing recipe provided in the polishing apparatus) is delivered into the polishing apparatus and that wafer is polished by the polishing apparatus, proper polishing of that wafer cannot be performed because the polishing recipe is not proper for that wafer and the polishing endpoint detection is not properly performed.

### SUMMARY

Therefore, there are provided a method and an optical film-thickness measuring apparatus capable of detecting a wrong workpiece (i.e., wafer) which is not an object to be polished.

Embodiments, which will be described below, relate to a technique for measuring a film thickness based on spectrum of light reflected from a workpiece, such as wafer, substrate, or panel, for use in manufacturing of semiconductor devices, and more particularly to a technique for detecting a wrong workpiece which is not an object to be polished.

In an embodiment, there is provided a method of detecting a wrong workpiece which is not an object to be polished, comprising: creating inspection spectrum data of reflected light from a workpiece before polishing of the workpiece or after beginning of polishing of the workpiece; inputting the inspection spectrum data to an autoencoder, the autoencoder being a trained model which has been constructed by machine learning using training data which includes a plurality of indicator spectra data of a plurality of reflected lights from a correct workpiece which is an object to be polished; calculating a difference between output data from the autoencoder and the inspection spectrum data; and determining that, when the difference is larger than a threshold value, the workpiece used to create the inspection spectrum data is a wrong workpiece which is not an object to be polished.

In an embodiment, creating the inspection spectrum data comprises creating the inspection spectrum data of reflected light from the workpiece during water-polishing of the workpiece performed before chemical mechanical polishing of the workpiece, or during an initial stage of chemical mechanical polishing of the workpiece.

In an embodiment, the method further comprises: classifying a plurality of spectra data acquired before polishing of a workpiece in the past or after beginning of polishing of a workpiece in the past into a plurality of groups in accordance with an algorithm of clustering; creating the training data including a plurality of indicator spectra data which belong to one of the plurality of groups; and performing the machine learning using the training data to construct the autoencoder which is the trained model, wherein the plurality of indicator spectra data belonging to one of the plurality of groups are a plurality of spectra data of a plurality of reflected lights from a correct workpiece which is an object to be polished.

In an embodiment, there is provided a method of detecting a wrong workpiece which is not an object to be polished, comprising: determining reference spectrum data from a plurality of indicator spectra data of a plurality of reflected lights from a correct workpiece which is an object to be polished; creating inspection spectrum data of reflected light from a workpiece before polishing of the workpiece or after beginning of polishing of the workpiece; calculating a difference between the reference spectrum data and the inspection spectrum data; and determining that, when the difference is larger than a threshold value, the workpiece used to create the inspection spectrum data is a wrong workpiece which is not an object to be polished.

In an embodiment, creating the inspection spectrum data comprises creating the inspection spectrum data of reflected light from the workpiece during water-polishing of the workpiece performed before chemical mechanical polishing of the workpiece, or during an initial stage of chemical mechanical polishing of the workpiece.

In an embodiment, the difference is Euclidean distance.

In an embodiment, determining the reference spectrum data comprises: classifying a plurality of spectra data acquired before polishing a workpiece in the past or after beginning of polishing of a workpiece in the past into a plurality of groups in accordance with an algorithm of clustering; and determining the reference spectrum data from a plurality of indicator spectra data which belong to one of the plurality of groups, wherein the plurality of indicator spectra data which belong to one of the plurality of groups are a plurality of spectra data of a plurality of reflected lights from a correct workpiece which is an object to be polished.

In an embodiment, the method further comprises: normalizing the plurality of indicator spectra data to create a plurality of normalized indicator spectra data, and normalizing the inspection spectrum data to create normalized inspection spectrum data.

In an embodiment, there is provided an optical film-thickness measuring apparatus for optically measuring a film thickness of a workpiece, comprising: a light source configured to emit light; an optical sensor head configured to irradiate the workpiece with the light emitted by the light source and receive reflected light from the workpiece; and a processing system configured to determine the film thickness of the workpiece based on spectrum measurement data of the reflected light from the workpiece, wherein the processing system is configured to: create inspection spectrum data of reflected light from the workpiece before polishing of the workpiece or after beginning of polishing of the workpiece; input the inspection spectrum data to an autoencoder, the autoencoder being a trained model which has been constructed by machine learning using training data which includes a plurality of indicator spectra data of a plurality of reflected lights from a correct workpiece which is an object to be polished; calculate a difference between output data from the autoencoder and the inspection spectrum data; and determine that, when the difference is larger than a threshold value, the workpiece used to create the inspection spectrum data is a wrong workpiece which is not an object to be polished.

In an embodiment, the processing system is configured to create the inspection spectrum data of reflected light from the workpiece during water-polishing of the workpiece performed before chemical mechanical polishing of the workpiece, or during an initial stage of chemical mechanical polishing of the workpiece.

In an embodiment, the processing system is configured to: classify a plurality of spectra data acquired before polishing of a workpiece in the past or after beginning of polishing of a workpiece in the past into a plurality of groups in accordance with an algorithm of clustering; create the training data including a plurality of indicator spectra data which belong to one of the plurality of groups; and perform the machine learning using the training data to construct the autoencoder which is the trained model, wherein the plurality of indicator spectra data belonging to one of the plurality of groups are a plurality of spectra data of a plurality of reflected lights from a correct workpiece which is an object to be polished.

In an embodiment, there is provided an optical film-thickness measuring apparatus for optically measuring a film thickness of a workpiece, comprising: a light source configured to emit light; an optical sensor head configured to irradiate the workpiece with the light emitted by the light source and receive reflected light from the workpiece; and a processing system configured to determine the film thickness of the workpiece based on spectrum measurement data of the reflected light from the workpiece, wherein the processing system is configured to: determine reference spectrum data from a plurality of indicator spectra data of a plurality of reflected lights from a correct workpiece which is an object to be polished; create inspection spectrum data of reflected light from the workpiece before polishing of the workpiece or after beginning of polishing of the workpiece; calculate a difference between the reference spectrum data and the inspection spectrum data; and determine that, when the difference is larger than a threshold value, the workpiece used to create the inspection spectrum data is a wrong workpiece which is not an object to be polished.

In an embodiment, the processing system is configured to create the inspection spectrum data of reflected light from the workpiece during water-polishing of the workpiece performed before chemical mechanical polishing of the workpiece, or during an initial stage of chemical mechanical polishing of the workpiece.

In an embodiment, the difference is Euclidean distance.

In an embodiment, the processing system is configured to: classify a plurality of spectra data acquired before polishing a workpiece in the past or after beginning of polishing of a workpiece in the past into a plurality of groups in accordance with an algorithm of clustering; and determine the reference spectrum data from a plurality of indicator spectra data which belong to one of the plurality of groups, wherein the plurality of indicator spectra data which belong to one of the plurality of groups are a plurality of spectra data of a plurality of reflected lights from a correct workpiece which is an object to be polished.

In an embodiment, the processing system is configured to: normalize the plurality of indicator spectra data to create a plurality of normalized indicator spectra data, and normalize the inspection spectrum data to create normalized inspection spectrum data.

The autoencoder is the trained model that has been constructed by the machine learning using the training data including the plurality of indicator spectra data of the plurality of reflected lights from the correct workpiece which is an object to be polished. More specifically, the machine learning is performed such that, when indicator spectrum data is input to the autoencoder, the autoencoder outputs substantially the same data as the input indicator spectrum data. When spectrum data of reflected light from a wrong workpiece, which is not an object to be polished, is input to the autoencoder, the autoencoder outputs data that is significantly different from the input spectrum data. Therefore, when the difference (which may be referred to as reconstruction error) between the input inspection spectrum data and the output data is larger than the threshold value, it can be determined that the workpiece that has been used to create the inspection spectrum data is a wrong workpiece which is not an object to be polished.

Similarly, when the difference between the predetermined reference spectrum data and the inspection spectrum data is larger than the threshold value, it can be determined that the workpiece that has been used to create the inspection spectrum data is a wrong workpiece which is not an object to be polished.

### BRIEF DESCRIPTION OF THE DRAWINGS

FIG. 1 is a schematic view showing an embodiment of a polishing apparatus;

FIG. 2 is a cross-sectional view showing a detailed configuration of an optical film-thickness measuring apparatus according to one embodiment;

FIG. 3 is a graph showing an example of spectrum measurement data;

FIG. 4 is a schematic diagram showing an example of an autoencoder;

FIG. 5 is a diagram showing an example when a spectrum data of reflected light from a correct workpiece, which is an object to be polished, is input to the autoencoder;

FIG. 6 is a diagram showing an example when a spectrum data of reflected light from a wrong workpiece, which is not an object to be polished, is input to the autoencoder;

FIG. 7 is a flowchart for illustrating one embodiment of determining whether or not a workpiece is a wrong workpiece which is not an object to be polished;

FIG. 8 is a diagram showing an example in which a plurality of spectra data are classified into three groups by clustering;

FIG. 9 is a flowchart for illustrating another embodiment of determining whether or not a workpiece is a wrong workpiece which is not an object to be polished;

FIG. 10A is a graph showing an example of a plurality of indicator spectra data before normalization, and FIG. 10B is a graph showing an example of a plurality of indicator spectra data after normalization; and

FIG. 11A is a graph showing a result of periodically calculating a difference between a reference spectrum data determined from a plurality of indicator spectra data before normalization and an inspection spectrum data before normalization, and FIG. 11B is a graph showing a result of periodically calculating a difference between a reference spectrum data determined from a plurality of indicator spectra data after normalization and an inspection spectrum data after normalization.

### DESCRIPTION OF EMBODIMENTS

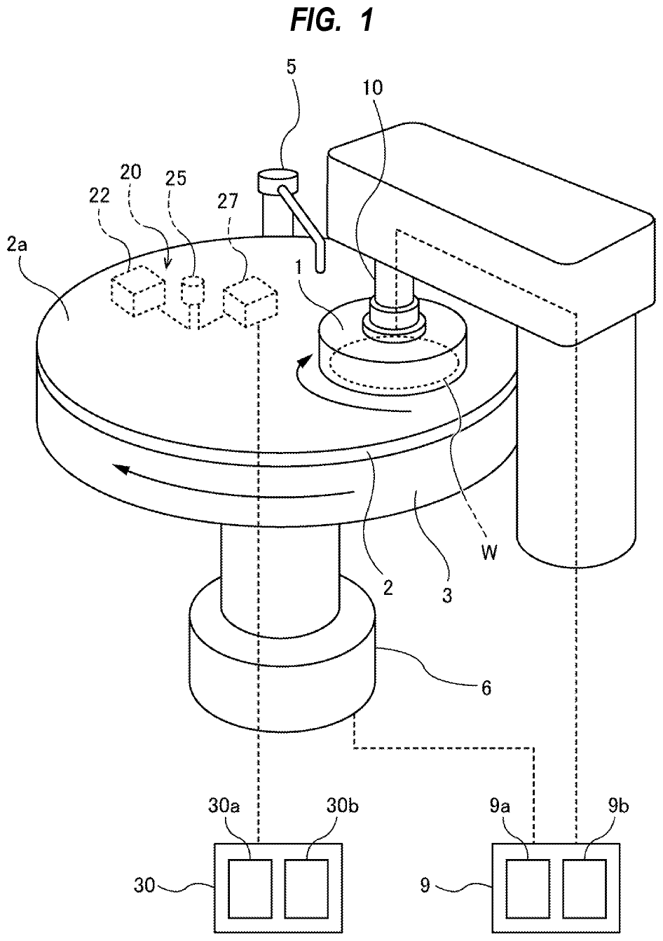

Hereinafter, embodiments will be described with reference to the drawings. FIG. 1 is a schematic view showing an embodiment of a polishing apparatus. As shown in FIG. 1, the polishing apparatus includes a polishing table 3 that supports a polishing pad 2, a polishing head 1 configured to press a workpiece W having a film against the polishing pad 2, a table motor 6 configured to rotate the polishing table 3, a polishing-liquid supply nozzle 5 configured to supply a polishing liquid, such as slurry, onto the polishing pad 2, and an operation controller 9 configured to control operations of the polishing apparatus. The polishing pad 2 has an upper surface that constitutes a polishing surface 2a for polishing the workpiece W. Examples of the workpiece W include a wafer, a substrate (e.g., a circular substrate, a polygonal substrate), and a panel which are used in manufacturing of semiconductor devices.

The polishing head 1 is coupled to a head shaft 10, which is coupled to a polishing-head motor (now shown). The polishing head motor is configured to rotate the polishing head 1 together with the head shaft 10 in a direction indicated by an arrow. The polishing table 3 is coupled to the table motor 6, which is configured to rotate the polishing table 3 and the polishing pad 2 in a direction indicated by an arrow. The polishing head 1, the polishing head motor, the polishing-liquid supply nozzle 5, and the table motor 6 are coupled to the operation controller 9.

Polishing of the workpiece W is performed as follows. The polishing-liquid supply nozzle 5 supplies the polishing liquid onto the polishing surface 2a of the polishing pad 2 on the polishing table 3, while the polishing table 3 and the polishing head 1 are rotated in the directions indicated by the arrows in FIG. 1. While the workpiece W is being rotated by the polishing head 1, the workpiece W is pressed by the polishing head 1 against the polishing surface 2a of the polishing pad 2 in the presence of the polishing liquid on the polishing pad 2. The surface of the workpiece W is polished by a chemical action of the polishing liquid and mechanical actions of abrasive grains contained in the polishing liquid and the polishing pad 2. Polishing of the workpiece W using such polishing liquid (e.g., slurry) is a chemical-mechanical polishing of the workpiece W.

The operation controller 9 includes a memory 9a storing programs therein, and a processor 9b configured to execute arithmetic operations according to instructions included in the programs. The operation controller 9 is composed of at least one computer. The memory 9a includes a main memory, such as a random access memory (RAM), and an auxiliary memory, such as a hard disk drive (HDD) or solid state drive (SSD). Examples of the processor 9b include a CPU (central processing unit) and a GPU (graphic processing unit). However, the specific configurations of the operation controller 9 are not limited to these examples.

The polishing apparatus includes an optical film-thickness measuring apparatus 20 configured to measure a thickness of the film of the workpiece W. The optical film-thickness measuring apparatus 20 includes a light source 22 configured to emit light, an optical sensor head 25 configured to irradiate the workpiece W with the light from the light source 22 and receive light reflected from the workpiece W, a spectrometer 27 coupled to the optical sensor head 25, and a processing system 30 configured to determine the thickness of the film of the workpiece W based on the reflected light from the workpiece W. The optical sensor head 25 is arranged in the polishing table 3 and rotates together with the polishing table 3. Although not shown, optical sensor heads 25 each coupled to the spectrometer 27 and the light source 22 may be provided.

The processing system 30 includes a memory 30a storing programs therein, and an arithmetic device 30b configured to execute arithmetic operations according to instructions included in the programs. The processing system 30 is composed of at least one computer. The memory 30a includes a main memory, such as a random access memory (RAM), and an auxiliary memory, such as a hard disk drive (HDD) or solid state drive (SSD). Examples of the arithmetic device 30b include a CPU (central processing unit) and a GPU (graphic processing unit). However, the specific configurations of the processing system 30 are not limited to these examples.

Each of the operation controller 9 and the processing system 30 may be comprised of computers. For example, each of the operation controller 9 and the processing system 30 may be a combination of edge server and cloud server. In one embodiment, the operation controller 9 and the processing system 30 may be constituted of a single computer.

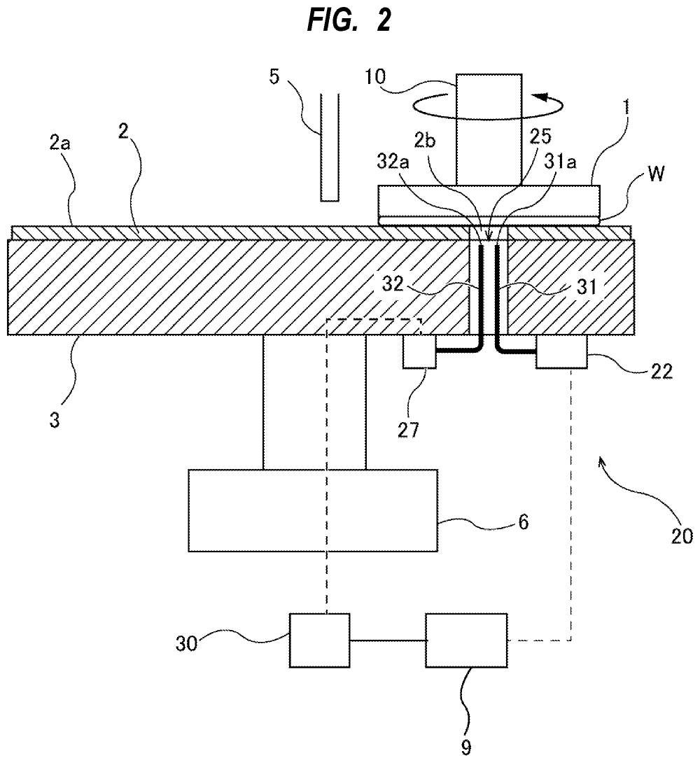

FIG. 2 is a cross-sectional view showing a detailed configuration of the optical film-thickness measuring apparatus 20 according to one embodiment. The optical film-thickness measuring apparatus 20 includes a light source 22 configured to emit light, a light-emitting optical fiber cable 31 coupled to the light source 22 and a light-receiving optical fiber cable 32 coupled to a spectrometer 27. A distal end 31a of the light-emitting optical fiber cable 31 and a distal end 32a of the light-receiving optical fiber cable 32 constitute the optical sensor head 25. Specifically, the light-emitting optical fiber cable 31 directs the light, emitted by the light source 22, to the workpiece W on the polishing pad 2, and the light-receiving optical fiber cable 32 receives the reflected light from the workpiece W and transmits the reflected light to the spectrometer 27.

The spectrometer 27 is coupled to the processing system 30. The light-emitting optical fiber cable 31, the light-receiving optical fiber cable 32, the light source 22, and the spectrometer 27 are mounted to the polishing table 3 and rotate together with the polishing table 3 and the polishing pad 2. The optical sensor head 25, composed of the distal end 31a of the light-emitting optical fiber cable 31 and the distal end 32a of the light-receiving optical fiber cable 32, is arranged so as to face the surface of the workpiece W on the polishing pad 2. A position of the optical sensor head 25 is such that the optical sensor head 25 traverses the surface of the workpiece W on the polishing pad 2 each time the polishing table 3 and polishing pad 2 make one rotation. The polishing pad 2 has a through-hole 2b located above the optical sensor head 25. The optical sensor head 25 irradiates the workpiece W with the light through the through-hole 2b and receives the reflected light from the workpiece W through the through-hole 2b each time the polishing table 3 makes one rotation.

The light source 22 may be a flash light source configured to repeatedly emit light at short time intervals. Examples of the light source 22 may include xenon flash lamp. The light source 22 is electrically coupled to the operation controller 9 and emits the light upon receiving a trigger signal sent from the operation controller 9. More specifically, while the optical sensor head 25 sweeps across the surface of the workpiece W on the polishing pad 2, the light source 22 receives a plurality of trigger signals and emits the light multiple times. Therefore, multiple measurement points on the workpiece W are irradiated with the light each time the polishing table 3 makes one rotation.

The light emitted by the light source 22 is transmitted through the light-emitting optical fiber cable 31 to the optical sensor head 25 and emitted from the optical sensor head 25. The light is incident on the workpiece W on the polishing pad 2 through the through-hole 2b of the polishing pad 2. The reflected light from the workpiece W passes through the through-hole 2b of the polishing pad 2 again and is received by the optical sensor head 25. The reflected light from the workpiece W is transmitted through light-receiving optical fiber cable 32 to the spectrometer 27.

The spectrometer 27 is configured to decompose the reflected light according to wavelengths and to measure intensity of the reflected light at each of the wavelengths over a predetermined wavelength range. Specifically, the spectrometer 27 decomposes the reflected light from the workpiece W according to wavelengths and measures the intensity of the reflected light at each of the wavelengths over the predetermined wavelength range to thereby generate spectrum measurement data. The spectrum measurement data is sent to the processing system 30.

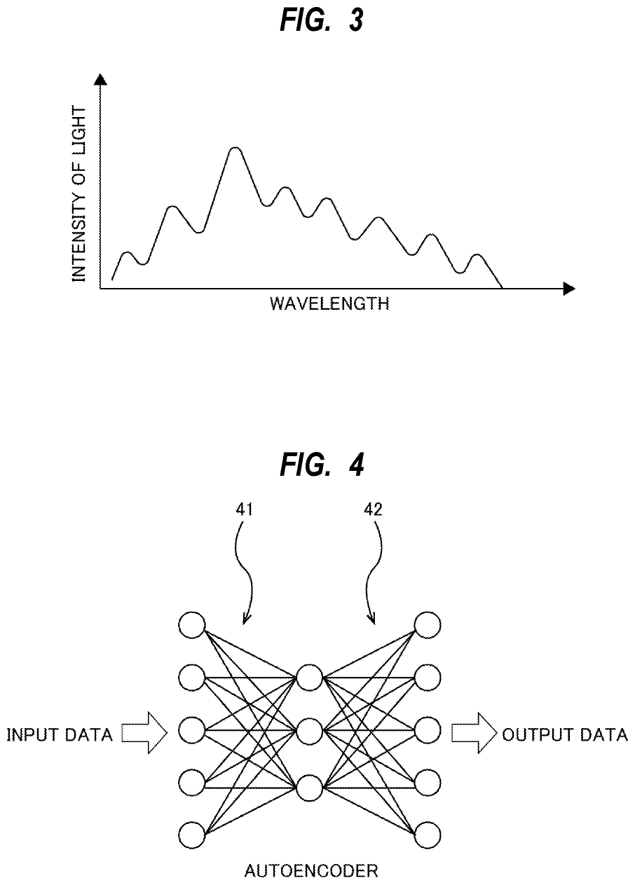

FIG. 3 is a graph showing an example of the spectrum measurement data. In FIG. 3, a vertical axis represents the intensity of the reflected light from the workpiece W, and a horizontal axis represents the wavelength of the reflected light. As shown in FIG. 3, the spectrum measurement data can be expressed as a spectrum (spectral waveform) indicating a relationship between the wavelength and intensity of the light.

The processing system 30 is configured to determine the film thickness of the workpiece W based on the spectrum measurement data of the reflected light from the workpiece W. The method of determining the film thickness of the workpiece W based on the spectrum measurement data utilizes a known technique. For example, the processing system 30 determines reference spectrum data, which is closest in shape to the spectrum measurement data, from a reference spectral library, and determines the film thickness associated with this reference spectrum data determined. In another example, the processing system 30 performs a Fourier transform on the spectrum measurement data, and determines the film thickness from a frequency spectrum obtained.

Polishing of the workpiece W is performed in accordance with a polishing recipe that has been set in the polishing apparatus. This polishing recipe includes a type of polishing liquid to be used, a rotation speed of the polishing table, a rotation speed of the polishing head, a pressing force of the polishing head against the workpiece W, conditions for measuring the film thickness, and conditions for detecting the polishing endpoint. The polishing recipe differs for each type of workpiece (i.e., a laminated structure that constitutes the surface of the workpiece). In particular, when the types of workpieces are different, spectra of the reflected light from the workpiece are different, and thus the conditions for detecting the polishing endpoint are also different.

If a workpiece that is not an object to be polished (i.e., a workpiece of a different type that does not correspond to the polishing recipe that has been set in the polishing apparatus) is delivered into the polishing apparatus and this workpiece is polished by the polishing apparatus, a proper polishing cannot be performed on the workpiece because the polishing recipe is not suitable for the workpiece, and the detection for the polishing endpoint is not performed properly.

Accordingly, in this embodiment, the processing system 30 is configured to determine whether the workpiece W is a correct workpiece that is an object to be polished or a wrong workpiece that is not an object to be polished before or after polishing of the workpiece W is started. The correct workpiece that is an object to be polished means a workpiece that corresponds to the polishing recipe that has been set in the polishing apparatus (i.e., a workpiece suitable for the polishing recipe), while the wrong workpiece that is not an object to be polished means a workpiece that does not correspond to the polishing recipe that has been set in the polishing apparatus (i.e., a workpiece unsuitable for the polishing recipe).

The processing system 30 creates inspection spectrum data of the reflected light from the workpiece W before or after polishing of the workpiece W is started, inputs the inspection spectrum data to an autoencoder, and calculates a difference between an output data from the autoencoder and the inspection spectrum data. The inspection spectrum data is created in the same way as the spectrum measurement data described with reference to FIGS. 2 and 3, and a detailed description of this process is omitted.

In one embodiment, a timing for creating the inspection spectrum data is a timing immediately before polishing of the workpiece W or immediately after beginning of polishing of the workpiece W. In one embodiment, the processing system 30 is configured to create the inspection spectrum data of reflected light from the workpiece W during water-polishing of the workpiece W which is performed prior to the chemical mechanical polishing of the workpiece W using the polishing liquid, such as slurry. The water-polishing of the workpiece W is performed with the polishing head 1 holding the workpiece W on the polishing surface 2a of the polishing pad 2 while water, instead of the polishing liquid (e.g. slurry), is supplied from the liquid supply nozzle 5 onto the polishing surface 2a of the polishing pad 2. Unlike the polishing liquid (e.g., slurry), the water does not have an etching function and does not contain abrasive grains. In addition, the polishing head 1 does not press the workpiece W strongly against the polishing pad 2 during the water-polishing. Therefore, polishing of the workpiece W during the water-polishing does not progress, and thus substantial polishing of the workpiece W is not started.

In one embodiment, the processing system 30 may create the inspection spectrum data of reflected light from the workpiece W during an initial stage of the chemical mechanical polishing of the workpiece W with use of the polishing liquid (e.g., slurry). Examples of the initial stage of the chemical mechanical polishing may include a period of time from start of the chemical mechanical polishing of the workpiece W until a predetermined amount of time elapse, or a period of time from start of the chemical mechanical polishing of the workpiece W until the polishing table 3 rotates a predetermined number of times. For example, the processing system 30 creates the inspection spectrum data of the reflected light from the workpiece W when the polishing table 3 is making its first rotation after the chemical-mechanical polishing of the workpiece W has been started.

As described above, the processing system 30 inputs, into the autoencoder, the inspection spectrum data which is created immediately before the chemical mechanical polishing of the workpiece W or immediately after beginning of the chemical mechanical polishing. The autoencoder is a trained model constructed by machine learning using training data which includes a plurality of indicator spectra data of a plurality of reflected lights from at least one correct workpiece which is an object to be polished. The plurality of indicator spectra data included in the training data are a plurality of previous spectra data acquired before the chemical mechanical polishing or after beginning of the chemical mechanical polishing of the correct workpiece which is an object to be polished. For example, the plurality of indicator spectra data included in the training data are a plurality of spectra data acquired during previous water-polishing or previous chemical mechanical polishing of the correct workpiece which is an object to be polished.

The number of correct workpieces used to create the plurality of indicator spectra data included in the training data may be one or more. In one embodiment, in order to increase an accuracy of the machine learning, the plurality of indicator spectra data are created using a plurality of correct workpieces, so that the training data including these indicator spectra data is created.

The arithmetic device 30b of the processing system 30 performs the machine learning using the training data in accordance with instructions contained in the program which is stored in the memory 30a, thereby constructing the autoencoder. The autoencoder, which is the trained model constructed by the machine learning, is stored in the memory 30a.

The machine learning is performed such that, when the indicator spectrum data is input to the autoencoder, the autoencoder outputs data that is substantially the same as the input indicator spectrum data. When spectrum data of reflected light from a wrong workpiece, which is not an object to be polished, is input to the autoencoder, the autoencoder outputs data that is greatly different from the input spectrum data.

The processing system 30 is configured to determine that, if a difference (also referred to as reconstruction error) between the inspection spectrum data input to the autoencoder and the data output from the autoencoder is larger than a threshold value, the workpiece used to create that inspection spectrum data is a wrong workpiece that is not an object to be polished.

FIG. 4 is a schematic diagram showing an example of the autoencoder. The autoencoder includes an encoder 41 configured to extract features of the input spectrum data, and a decoder 42 configured to reconstruct the input spectrum data from the extracted features.

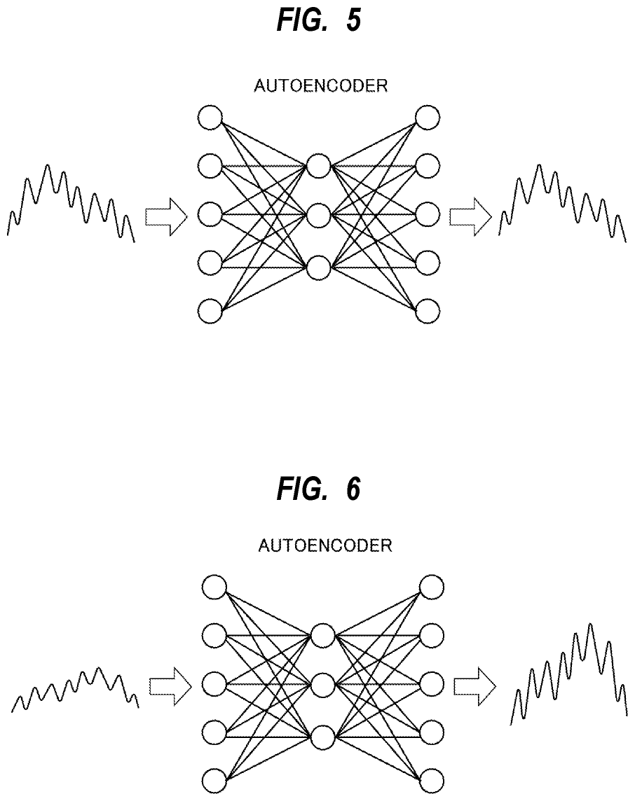

FIG. 5 is a diagram showing an example when a spectrum data of reflected light from a correct workpiece, which is an object to be polished, is input to the autoencoder. When a spectrum data of the correct workpiece is input to the autoencoder as shown in FIG. 5, the autoencoder outputs substantially the same output data as the input spectrum data, because the autoencoder is a trained model constructed by the machine learning using the training data including the plurality of indicator spectra data from the correct workpiece which is an object to be polished. Therefore, the difference between the input spectrum data and the output data is small (i.e., the reconstruction error is small).

FIG. 6 is a diagram showing an example when a spectrum data of reflected light from a wrong workpiece, which is not an object to be polished, is input to the autoencoder. As shown in FIG. 6, when a spectrum data of reflected light from a wrong workpiece, which is not an object to be polished, is input to the autoencoder, the autoencoder outputs an output data that is greatly different from the input spectrum data. Therefore, the difference between the input spectrum data and the output data (reconstruction error) is large.

In this manner, the processing system 30 determines whether the workpiece W is a correct workpiece which is an object to be polished or a wrong workpiece which is not an object to be polished based on the difference between the inspection spectrum data of the workpiece W and the output data acquired from the autoencoder. When the processing system 30 determines that the workpiece W is a wrong workpiece which is not an object to be polished, the processing system 30 sends the determination result to the operation controller 9. Upon receiving the determination result, the operation controller 9 does not allow the polishing apparatus to perform the chemical mechanical polishing of the workpiece W, or instructs the polishing apparatus to stop the chemical mechanical polishing of the workpiece W. Alternatively, upon receiving the determination result, the operation controller 9 may change the polishing recipe that has been set in the polishing apparatus to a polishing recipe prepared in advance for the workpiece W.

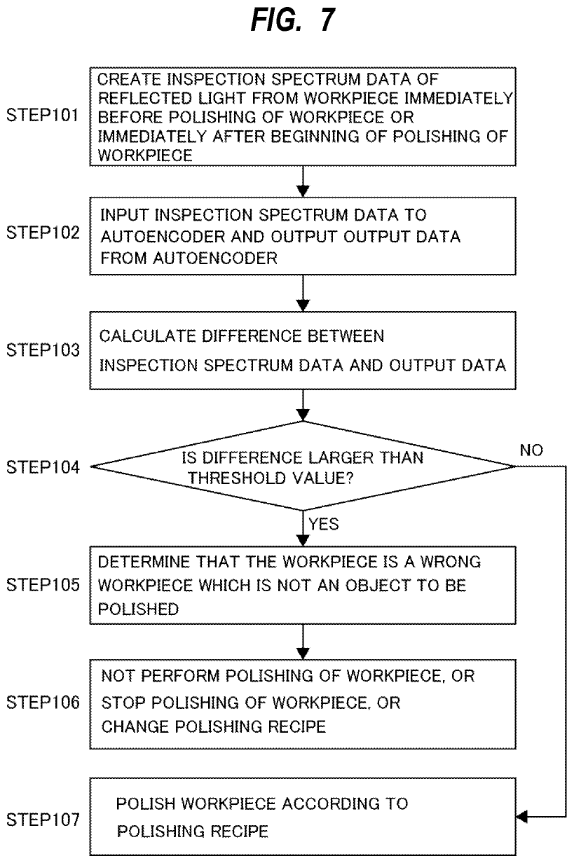

FIG. 7 is a flowchart for illustrating one embodiment of determining whether or not the workpiece W is a wrong workpiece which is not an object to be polished.

In step 101, the processing system 30 creates the inspection spectrum data of reflected light from the workpiece W immediately before polishing of the workpiece W or immediately after beginning of polishing of the workpiece W. For example, the processing system 30 creates the inspection spectrum data of reflected light from the workpiece W during the water-polishing of the workpiece W or during the initial stage of the chemical mechanical polishing of the workpiece W.

In step 102, the processing system 30 inputs the inspection spectrum data created in the step 101 mentioned above to the autoencoder, and outputs the output data from the autoencoder.

In step 103, the processing system 30 calculates the difference between the inspection spectrum data created in the step 101 mentioned above and the output data output from the autoencoder.

In step 104, the processing system 30 determines whether or not the difference is larger than a threshold value.

In step 105, the processing system 30 determines that the workpiece W is a wrong workpiece which is not an object to be polished when the difference is larger than the threshold value.

In step 106, the processing system 30 sends the determination result of the workpiece W to the operation controller 9. Upon receiving the determination result, the operation controller 9 either does not allow the polishing apparatus to perform polishing of the workpiece W, instructs the polishing apparatus to stop polishing of the workpiece W, or changes the polishing recipe that has been set in the polishing apparatus to a polishing recipe prepared in advance for the workpiece W.

In step 107, when the difference is less than the threshold value, the processing system 30 instructs the polishing apparatus to polish the workpiece W in accordance with the polishing recipe that has been set in the polishing apparatus.

The training data used in the machine learning of the autoencoder includes only the indicator spectra data of the correct workpiece, which is an object to be polished, among a large number of spectra data acquired during previous water-polishing or previous chemical mechanical polishing of workpieces. If a large number of spectra data acquired during previous water-polishing or previous chemical mechanical polishing of workpieces include spectra data of a wrong workpiece which is not an object to be polished, such spectra data should not be used in the training data. In other words, it is necessary to extract only the indicator spectra data of the correct workpiece from a large number of spectra data. However, such operation entails a large amount of effort.

Accordingly, in one embodiment, the processing system 30 classifies a plurality of spectra data acquired before previous chemical mechanical polishing of workpieces or after beginning of chemical mechanical polishing of workpieces into a plurality of groups in accordance with an algorithm of clustering. For example, the processing system 30 classifies a plurality of spectra data acquired during previous water-polishing or previous chemical mechanical polishing into a plurality of groups in accordance with an algorithm of clustering. Next, the processing system 30 produces the training data including a plurality of indicator spectra data belonging to one of the plurality of groups, and performs the machine learning using the training data to construct the autoencoder which is a trained model. The plurality of indicator spectra data belonging to one of the plurality of groups is a plurality of spectra data of a plurality of reflected light from correct workpiece(s) which is an object to be polished.

The clustering is called cluster analysis, and the clustering algorithm is a type of artificial intelligence algorithm that classifies a plurality of spectra data based on their features. The memory 30a of the processing system 30 stores a program for classifying a plurality of spectra data into groups according to the algorithm of the clustering. The arithmetic device 30b of the processing system 30 classifies the plurality of spectra data into groups by performing arithmetic operations according to instructions included in the program.

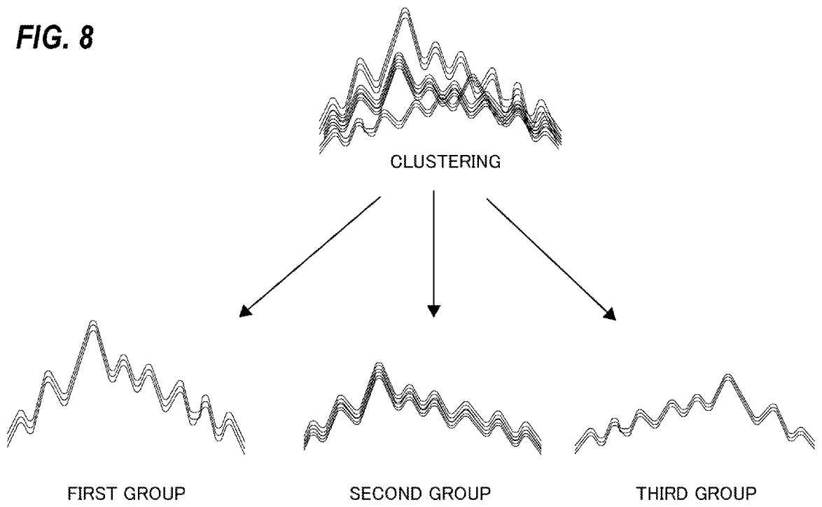

FIG. 8 is a diagram showing an example of classifying a plurality of spectra data into three groups by the clustering. In the example shown in FIG. 8, the processing system 30 performs the machine learning using, as training data, spectra data included in a second group which is a group of indicator spectra data. The clustering can quickly classify a huge number of previously acquired spectra data into indicator spectra data and other spectra data. In the example shown in FIG. 8, the plurality of spectra data are divided into the three groups, while they may be divided into two groups or four or more groups.

Next, another embodiment of determining whether or not the workpiece W is a wrong workpiece which is not an object to be polished will be described. Configurations and operations of the optical film-thickness measuring apparatus 20 used in this embodiment are the same as those of the embodiments described with reference to FIGS. 1 to 8, and redundant descriptions thereof will be omitted.

In this embodiment, the processing system 30 is configured to determine a reference spectrum data from a plurality of indicator spectra data of reflected lights from a correct workpiece which is an object to be polished, create inspection spectrum data of reflected light from the workpiece W before polishing of the workpiece W or after beginning of polishing of the workpiece W, calculate a difference between the reference spectrum data and the inspection spectrum data, and determine that, when the difference is larger than a threshold value, the workpiece W used to create the inspection spectrum data is a wrong workpiece which is not an object to be polished.

In one embodiment, a timing for creating the inspection spectrum data is a timing immediately before polishing of the workpiece W or immediately after beginning of polishing of the workpiece W. In one embodiment, the processing system 30 is configured to create the inspection spectrum data of reflected light from the workpiece W during water-polishing of the workpiece W which is performed prior to the chemical mechanical polishing of the workpiece W. In another embodiment, the processing system 30 is configured to create the inspection spectrum data of reflected light from the workpiece W during the initial stage of the chemical mechanical polishing of the workpiece W.

The reference spectrum data may be one or an average of the plurality of indicator spectra data of the plurality of reflected lights from the correct workpiece which is an object to be polished. The plurality of indicator spectra data are a plurality of previous spectra data acquired before polishing of the correct workpiece or after beginning of polishing of the correct workpiece which is an object to be polished. For example, the plurality of indicator spectra data may be a plurality of spectra data acquired during previous water-polishing or chemical mechanical polishing of the correct workpiece which is an object to be polished.

The number of correct workpieces used to create the plurality of indicator spectra data may be one or more. In one embodiment, in order to improve the accuracy of the reference spectrum data, the plurality of indicator spectra data are created using a plurality of correct workpieces, so that the reference spectrum data is determined from these indicator spectra data. The reference spectrum data is stored in the memory 30a.

The processing system 30 calculates the difference between the reference spectrum data and the inspection spectrum data. In this embodiment, the processing system 30 is configured to calculate Euclidean distance as the difference between the reference spectrum data and the inspection spectrum data.

When the difference between the reference spectrum data and the inspection spectrum data is smaller than the threshold value, the processing system 30 determines that the workpiece W used to create the inspection spectrum data is a correct workpiece which is an object to be polished. In contrast, when the difference between the reference spectrum data and the inspection spectrum data is larger than the threshold value, the processing system 30 determines that the workpiece W used to create the inspection spectrum data is a wrong workpiece which is not an object to be polished.

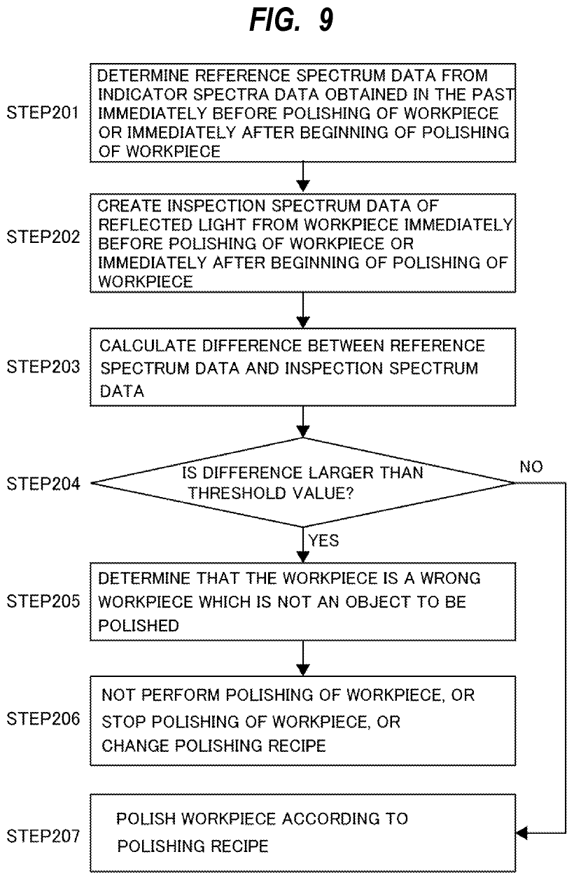

FIG. 9 is a flowchart for illustrating one embodiment of determining whether or not the workpiece W is a wrong workpiece which is not an object to be polished.

In step 201, the processing system 30 determines the reference spectrum data from the plurality of indicator spectra data acquired in the past. The plurality of indicator spectra data acquired in the past are the plurality of spectra data acquired before polishing of a correct workpiece or after beginning of polishing of a correct workpiece which is an object to be polished. For example, the plurality of indicator spectra data in the past is the plurality of spectra data acquired during previous water-polishing of the correct workpiece or previous chemical mechanical polishing of the correct workpiece which is an object to be polished. In one embodiment, the reference spectrum data is one of the plurality of indicator spectra data acquired in the past, or an average of the plurality of indicator spectra data acquired in the past.

In step 202, the processing system 30 creates the inspection spectrum data of reflected light from the workpiece W immediately before polishing of the workpiece W or immediately after beginning of polishing of the workpiece W. For example, the processing system 30 is configured to create the inspection spectrum data of reflected light from the workpiece W during water-polishing of the workpiece W or during the initial stage of chemical mechanical polishing of the workpiece W.

In step 203, the processing system 30 calculates the difference between the reference spectrum data and the inspection spectrum data.

In step 204, the processing system 30 determines whether or not the difference is larger than the threshold value.

In step 205, the processing system 30 determines that the workpiece W is a wrong workpiece, which is not an object to be polished, when the difference is larger than the threshold value.

In step 206, the processing system 30 sends the determination result of the workpiece W to the operation controller 9. Upon receiving the determination result, the operation controller 9 either does not allow the polishing apparatus to perform polishing of the workpiece W, instructs the polishing apparatus to stop polishing of the workpiece W, or changes the polishing recipe that has been set in the polishing apparatus to a polishing recipe prepared in advance for the workpiece W.

In step 207, when the difference is less than the threshold value, the processing system 30 instructs the polishing apparatus to polish the workpiece W in accordance with the polishing recipe that has been set in the polishing apparatus.

The clustering described with reference to FIG. 8 can be applied to this embodiment. Specifically, the processing system 30 may be configured to classify a plurality of spectra data acquired in the past into a plurality of groups in accordance with the clustering algorithm, and to determine the reference spectrum data from a plurality of indicator spectra data belonging to one of the plurality of groups.

In one embodiment, the processing system 30 may be configured to normalize a plurality of previously acquired indicator spectra data to create a plurality of normalized indicator spectra data and determine reference spectrum data from the plurality of normalized indicator spectra data. Furthermore, the processing system 30 may be configured to normalize the inspection spectrum data to create normalized inspection spectrum data.

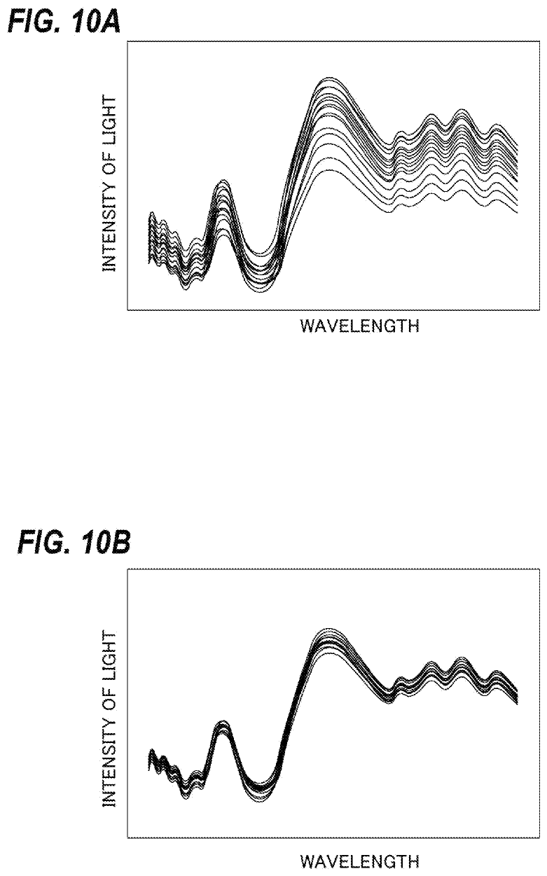

FIG. 10A is a graph showing an example of a plurality of indicator spectra data before normalization, and FIG. 10B is a graph showing an example of a plurality of indicator spectra data after normalization. As can be seen from comparison between FIG. 10A and FIG. 10B, normalization can decrease a variation in levels of the indicator spectra data.

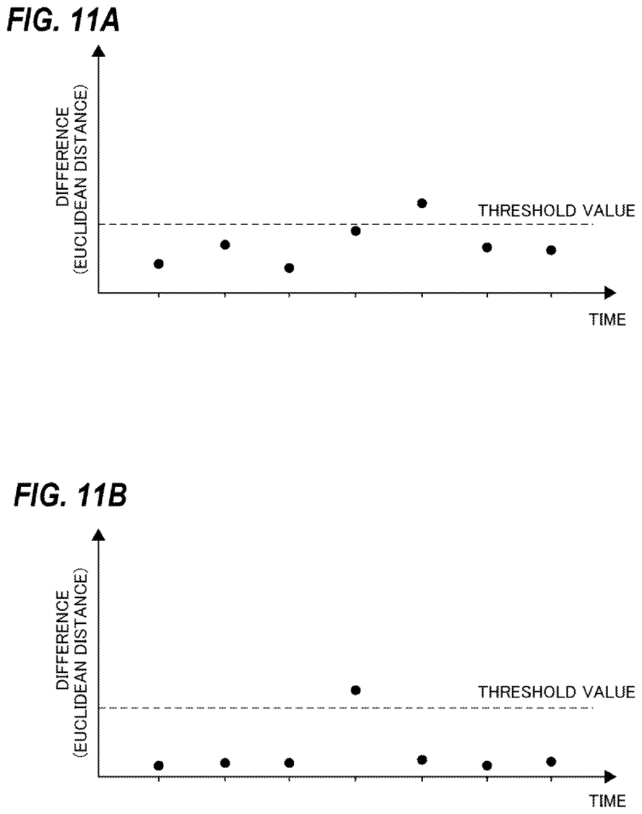

FIG. 11A is a graph showing a result of periodically calculating a difference between a reference spectrum data determined from a plurality of indicator spectra data before normalization and an inspection spectrum data before normalization, and FIG. 11B is a graph showing a result of periodically calculating a difference between a reference spectrum data determined from a plurality of indicator spectra data after normalization and an inspection spectrum data after normalization. In FIGS. 11(a) and 11(b), a vertical axis represents a difference (Euclidean distance) between the reference spectrum data and the inspection spectrum data, and a horizontal axis represents time.

As can be seen from comparison between FIG. 11A and FIG. 11B, the normalization process can decrease the variation in the difference between the reference spectrum data and the inspection spectrum data. As a result, the processing system 30 can correctly determine whether or not the workpiece W is a correct workpiece which is an object to be polished.

In the embodiments described above, one optical sensor head 25 is provided, while the present invention is not limited to the embodiments described above. A plurality of optical sensor heads 25 may be provided in the polishing table 3. For example, a plurality of optical sensor heads 25 may be arranged such that the plurality of optical sensor heads 25 move across different parts of the workpiece W (e.g., a center area and an edge area) as the polishing table 3 rotates.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A method of detecting a wrong workpiece which is not an object to be polished, comprising:
creating inspection spectrum data of reflected light from a workpiece before polishing of the workpiece or after beginning of polishing of the workpiece;
inputting the inspection spectrum data to an autoencoder, the autoencoder being a trained model which has been constructed by machine learning using training data which includes a plurality of indicator spectra data of a plurality of reflected lights from a correct workpiece which is an object to be polished;
calculating a difference between output data from the autoencoder and the inspection spectrum data; and
determining that, when the difference is larger than a threshold value, the workpiece used to create the inspection spectrum data is a wrong workpiece which is not an object to be polished.

2. The method according to claim 1, wherein creating the inspection spectrum data comprises creating the inspection spectrum data of reflected light from the workpiece during water-polishing of the workpiece performed before chemical mechanical polishing of the workpiece, or during an initial stage of chemical mechanical polishing of the workpiece.

3. The method according to claim 1, further comprising:
classifying a plurality of spectra data acquired before polishing of a workpiece in the past or after beginning of polishing of a workpiece in the past into a plurality of groups in accordance with an algorithm of clustering;
creating the training data including a plurality of indicator spectra data which belong to one of the plurality of groups; and
performing the machine learning using the training data to construct the autoencoder which is the trained model,
wherein the plurality of indicator spectra data belonging to one of the plurality of groups are a plurality of spectra data of a plurality of reflected lights from a correct workpiece which is an object to be polished.

4. A method of detecting a wrong workpiece which is not an object to be polished, comprising:
determining reference spectrum data from a plurality of indicator spectra data of a plurality of reflected lights from a correct workpiece which is an object to be polished;
creating inspection spectrum data of reflected light from a workpiece before polishing of the workpiece or after beginning of polishing of the workpiece;
calculating a difference between the reference spectrum data and the inspection spectrum data; and
determining that, when the difference is larger than a threshold value, the workpiece used to create the inspection spectrum data is a wrong workpiece which is not an object to be polished.

5. The method according to claim 4, wherein creating the inspection spectrum data comprises creating the inspection spectrum data of reflected light from the workpiece during water-polishing of the workpiece performed before chemical mechanical polishing of the workpiece, or during an initial stage of chemical mechanical polishing of the workpiece.

6. The method according to claim 4, wherein the difference is Euclidean distance.

7. The method according to claim 4, wherein determining the reference spectrum data comprises:
classifying a plurality of spectra data acquired before polishing a workpiece in the past or after beginning of polishing of a workpiece in the past into a plurality of groups in accordance with an algorithm of clustering; and
determining the reference spectrum data from a plurality of indicator spectra data which belong to one of the plurality of groups,
wherein the plurality of indicator spectra data which belong to one of the plurality of groups are a plurality of spectra data of a plurality of reflected lights from a correct workpiece which is an object to be polished.

8. The method according to claim 4, further comprising:
normalizing the plurality of indicator spectra data to create a plurality of normalized indicator spectra data, and
normalizing the inspection spectrum data to create normalized inspection spectrum data.

9. An optical film-thickness measuring apparatus for optically measuring a film thickness of a workpiece, comprising:
a light source configured to emit light;
an optical sensor head configured to irradiate the workpiece with the light emitted by the light source and receive reflected light from the workpiece; and
a processing system configured to determine the film thickness of the workpiece based on spectrum measurement data of the reflected light from the workpiece,
wherein the processing system is configured to:
create inspection spectrum data of reflected light from the workpiece before polishing of the workpiece or after beginning of polishing of the workpiece;
input the inspection spectrum data to an autoencoder, the autoencoder being a trained model which has been constructed by machine learning using training data which includes a plurality of indicator spectra data of a plurality of reflected lights from a correct workpiece which is an object to be polished;
calculate a difference between output data from the autoencoder and the inspection spectrum data; and
determine that, when the difference is larger than a threshold value, the workpiece used to create the inspection spectrum data is a wrong workpiece which is not an object to be polished.

10. The optical film-thickness measuring apparatus according to claim 9, wherein the processing system is configured to create the inspection spectrum data of reflected light from the workpiece during water-polishing of the workpiece performed before chemical mechanical polishing of the workpiece, or during an initial stage of chemical mechanical polishing of the workpiece.

11. The optical film-thickness measuring apparatus according to claim 9, wherein the processing system is configured to:
classify a plurality of spectra data acquired before polishing of a workpiece in the past or after beginning of polishing of a workpiece in the past into a plurality of groups in accordance with an algorithm of clustering;
create the training data including a plurality of indicator spectra data which belong to one of the plurality of groups; and
perform the machine learning using the training data to construct the autoencoder which is the trained model,
wherein the plurality of indicator spectra data belonging to one of the plurality of groups are a plurality of spectra data of a plurality of reflected lights from a correct workpiece which is an object to be polished.

12. An optical film-thickness measuring apparatus for optically measuring a film thickness of a workpiece, comprising:
a light source configured to emit light;
an optical sensor head configured to irradiate the workpiece with the light emitted by the light source and receive reflected light from the workpiece; and
a processing system configured to determine the film thickness of the workpiece based on spectrum measurement data of the reflected light from the workpiece,
wherein the processing system is configured to:
determine reference spectrum data from a plurality of indicator spectra data of a plurality of reflected lights from a correct workpiece which is an object to be polished;
create inspection spectrum data of reflected light from the workpiece before polishing of the workpiece or after beginning of polishing of the workpiece;
calculate a difference between the reference spectrum data and the inspection spectrum data; and
determine that, when the difference is larger than a threshold value, the workpiece used to create the inspection spectrum data is a wrong workpiece which is not an object to be polished.

13. The optical film-thickness measuring apparatus according to claim 12, wherein the processing system is configured to create the inspection spectrum data of reflected light from the workpiece during water-polishing of the workpiece performed before chemical mechanical polishing of the workpiece, or during an initial stage of chemical mechanical polishing of the workpiece.

14. The optical film-thickness measuring apparatus according to claim 12, wherein the difference is Euclidean distance.

15. The optical film-thickness measuring apparatus according to claim 12, wherein the processing system is configured to:
classify a plurality of spectra data acquired before polishing a workpiece in the past or after beginning of polishing of a workpiece in the past into a plurality of groups in accordance with an algorithm of clustering; and
determine the reference spectrum data from a plurality of indicator spectra data which belong to one of the plurality of groups,
wherein the plurality of indicator spectra data which belong to one of the plurality of groups are a plurality of spectra data of a plurality of reflected lights from a correct workpiece which is an object to be polished.

16. The optical film-thickness measuring apparatus according to claim 12, wherein the processing system is configured to:
normalize the plurality of indicator spectra data to create a plurality of normalized indicator spectra data, and
normalize the inspection spectrum data to create normalized inspection spectrum data.
